(19) United States
(12) Patent Application Publication
(10) Pub. No.: US 2017/0069840 A1
(43) Pub. Date: Mar. 9, 2017

(54) SEMICONDUCTOR MEMORY DEVICE

(71) Applicant: Kabushiki Kaisha Toshiba, Minato-ku (JP)

(72) Inventors: Masayuki ICHIGE, Yokkaichi (JP); Kikuko SUGIMAE, Kuwana (JP); Masumi SAITOH, Yokkaichi (JP); Kiyoshi OKUYAMA, Yokkaichi (JP)

(73) Assignee: Kabushiki Kaisha Toshiba, Minato-ku (JP)

(21) Appl. No.: 15/049,248

(22) Filed: Feb. 22, 2016

Related U.S. Application Data
(60) Provisional application No. 62/214,556, filed on Sep. 4, 2015.

(51) Int. Cl. H01L 45/00

(52) U.S. Cl. CPC H01L 45/14; H01L 45/1233; H01L 45/1253

(57) ABSTRACT

According to one embodiment, a semiconductor memory device includes first-third conductive layers, a semiconductor layer, a resistance change layer and a metal-containing layer. The second conductive layer is separated from the first conductive layer in a first direction. The semiconductor layer is provided between the first and the second conductive layers. The third conductive layer is arranged with the first semiconductor layer in a direction crossing the first direction. The first resistance change layer is provided between the first semiconductor layer and the first conductive layer. The first metal-containing layer is provided between the first resistance change layer and the first conductive layer. The first conductive layer extends in a second direction crossing the first direction. The second conductive layer extends in a third direction crossing the first direction and crossing the second direction. The third conductive layer extends in a direction crossing the first direction.

### CROSS-REFERENCE TO RELATED APPLICATIONS

This application is based upon and claims the benefit of priority from U.S. Provisional Patent Application 62/214,556, filed on Sep. 4, 2015; the entire contents of which are incorporated herein by reference.

### FIELD

Embodiments relate to a semiconductor memory device.

### BACKGROUND

There has been proposed a cross-point type semiconductor memory device provided with two conductive layers and a resistance change layer located between the two conductive layers.

### BRIEF DESCRIPTION OF THE DRAWINGS

FIG. 1 is a perspective view illustrating an example of a semiconductor memory device according to a first embodiment;

FIG. 2A is a schematic cross-sectional view illustrating a part of a semiconductor memory device according to the first embodiment;

FIG. 2B is a schematic cross-sectional view illustrating a part of a semiconductor memory device according to a second embodiment;

FIG. 3A is a schematic cross-sectional view illustrating a part of a semiconductor memory device according to a third embodiment;

FIG. 3B is a schematic cross-sectional view illustrating a part of a semiconductor memory device according to a fourth embodiment;

FIG. 4A is a schematic cross-sectional view illustrating a part of a semiconductor memory device according to a fifth embodiment;

FIG. 4B is a schematic cross-sectional view illustrating a part of another example of the semiconductor memory device according to the fifth embodiment;

FIG. 4C is a schematic cross-sectional view illustrating a part of another example of the semiconductor memory device according to the fifth embodiment;

FIG. 5A is a schematic cross-sectional view illustrating a part of a semiconductor memory device according to a sixth embodiment;

FIG. 5B is a schematic cross-sectional view illustrating a part of another example of the semiconductor memory device according to the sixth embodiment;

FIG. 5C is a schematic cross-sectional view illustrating a part of another example of the semiconductor memory device according to the sixth embodiment;

FIG. 6A is a schematic cross-sectional view illustrating a part of a semiconductor memory device according to a seventh embodiment;

FIG. 6B is a schematic cross-sectional view illustrating a part of another example of the semiconductor memory device according to the seventh embodiment;

FIG. 6C is a schematic cross-sectional view illustrating a part of another example of the semiconductor memory device according to the seventh embodiment;

FIG. 7A is a schematic cross-sectional view illustrating a part of a semiconductor memory device according to an eighth embodiment;

FIG. 7B is a schematic cross-sectional view illustrating a part of another example of the semiconductor memory device according to the eighth embodiment;

FIG. 7C is a schematic cross-sectional view illustrating a part of another example of the semiconductor memory device according to the eighth embodiment;

FIG. 8A is a schematic cross-sectional view illustrating a part of a semiconductor memory device according to a ninth embodiment;

FIG. 8B is a schematic cross-sectional view illustrating a part of another example of the semiconductor memory device according to the ninth embodiment;

FIG. 9A is a schematic cross-sectional view illustrating a part of a semiconductor memory device according to a tenth embodiment;

FIG. 9B is a schematic cross-sectional view illustrating a part of another example of the semiconductor memory device according to the tenth embodiment;

FIG. 10A and FIG. 10B are schematic cross-sectional views illustrating a method of manufacturing the semiconductor memory device according to the sixth embodiment;

FIG. 11A and FIG. 11B are schematic cross-sectional views illustrating the method of manufacturing the semiconductor memory device according to the sixth embodiment;

FIG. 12A and FIG. 12B are schematic cross-sectional views illustrating the method of manufacturing the semiconductor memory device according to the sixth embodiment;

FIG. 13A and FIG. 13B are schematic cross-sectional views illustrating the method of manufacturing the semiconductor memory device according to the sixth embodiment;

FIG. 14A and FIG. 14B are schematic cross-sectional views illustrating the method of manufacturing the semiconductor memory device according to the sixth embodiment;

FIG. 15A and FIG. 15B are schematic cross-sectional views illustrating the method of manufacturing the semiconductor memory device according to the sixth embodiment;

FIG. 16A and FIG. 16B are schematic cross-sectional views illustrating the method of manufacturing the semiconductor memory device according to the sixth embodiment;

FIG. 17A and FIG. 17B are schematic cross-sectional views illustrating the method of manufacturing the semiconductor memory device according to the sixth embodiment;

FIG. 18A and FIG. 18B are schematic cross-sectional views illustrating the method of manufacturing the semiconductor memory device according to the sixth embodiment;

FIG. 19A and FIG. 19B are schematic cross-sectional views illustrating the method of manufacturing the semiconductor memory device according to the sixth embodiment.

### DETAILED DESCRIPTION

According to one embodiment, a semiconductor memory device includes a first conductive layer, a second conductive layer, a first semiconductor layer, a third conductive layer, a first resistance change layer and a first metal-containing layer. The second conductive layer is provided to be separated from the first conductive layer in a first direction. The first semiconductor layer is provided between the first conductive layer and the second conductive layer. The third conductive layer is arranged with the first semiconductor layer in a direction crossing the first direction. The first resistance change layer is provided between the first semiconductor layer and the first conductive layer. The first metal-containing layer is provided between the first resistance change layer and the first conductive layer. The first conductive layer extends in a second direction crossing the first direction. The second conductive layer extends in a third direction crossing the first direction and crossing the second direction. The third conductive layer extends in a direction crossing the first direction.

### First Embodiment

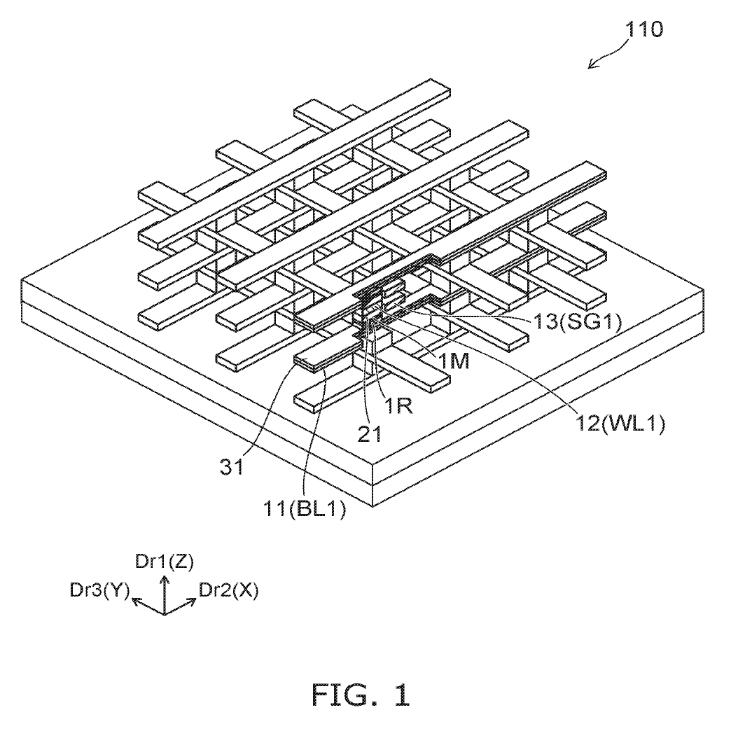

FIG. 1 is a perspective view illustrating an example of a semiconductor memory device according to a first embodiment.

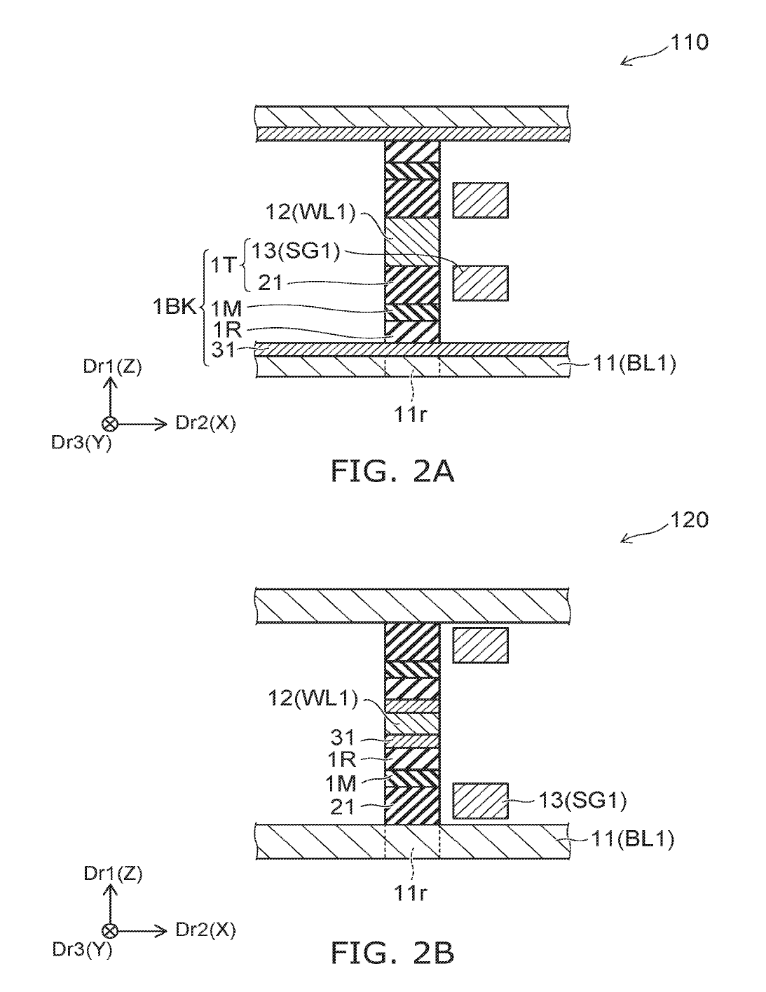

FIG. 2A is a schematic cross-sectional view illustrating a part of a semiconductor memory device according to the first embodiment.

As shown in FIG. 1 and FIG. 2A, the semiconductor memory device 110 according to the embodiment includes first bit lines BL1 (a first conductive layer 11), first word lines WL1 (a second conductive layer 12), first TFT channels (a first semiconductor layer 21), first gate electrodes SG1 (a third conductive layer 13), memory base members (a first resistance change layer 1R), and ion source metal (a first metal-containing layer 31). A first transistor 1T includes, for example, the first semiconductor layer 21 and the third conductive layer 13.

In the semiconductor memory device 110 according to the embodiment, the first transistor 1T and the first resistance change layer 1R are disposed between the first conductive layer 11 and the second conductive layer 12. The semiconductor memory device 110 is a resistance change memory including, for example, the first transistor 1T and the first resistance change layer 1R.

The first conductive layer 11 includes a first region 11r. The second conductive layer 12 is provided so as to be separated from the first conductive layer 11 in a first direction Dr1. The first conductive layer 11 extends in, for example, a second direction Dr2 crossing the first direction Dr1. The second conductive layer 12 extends in, for example, a third direction Dr3 crossing the first direction Dr1 and crossing the second direction Dr2. The first semiconductor layer 21 is provided between the first region 11r and the second conductive layer 12. The third conductive layer 13 is arranged with the first semiconductor layer 21 in the second direction Dr2. The third conductive layer 13 extends in, for example, the third direction Dr3.

The first resistance change layer 1R is provided between the first semiconductor layer 21 and the first conductive layer 11. The first metal-containing layer 31 is provided between the first resistance change layer 1R and the first region 11r. It is also possible for the first metal-containing layer 31 to extend in, for example, the second direction Dr2.

It is also possible for the semiconductor memory device 110 according to the embodiment to further include a current-limiting layer (a first intermediate layer 1M) provided between the first semiconductor layer 21 and the first resistance change layer 1R. The first block BLK1 includes, for example, the first semiconductor layer 21, the third conductive layer 13, the first resistance change layer 1R, and the first metal-containing layer 31.

The first direction Dr1 is, for example, a Z-direction. The second direction Dr2 is, for example, an X-direction. The third direction Dr3 is, for example, a Y-direction.

The first conductive layer 11 is, for example, the first bit line BL1. The second conductive layer 12 is, for example, the first word line WL1. The first resistance change layer 1R is provided between the first conductive layer 11 (the first bit line BL1) and the second conductive layer 12 (the first word line WL1).

When applying, for example, a voltage VT between the first conductive layer 11 and the second conductive layer 12, the resistance of the first resistance change layer 1R drops. Thus, a current flows through the first resistance change layer 1R.

When applying, for example, a voltage VR lower than the voltage VT between the first conductive layer 11 and the second conductive layer 12, the resistance of the first resistance change layer 1R increases. Thus, the current becomes difficult to flow through the first resistance change layer 1R. The resistance change layer 1R varies in resistance in accordance with the voltage applied. The first resistance change layer 1R acts as a resistance change memory.

The third conductive layer 13 is, for example, the first gate electrode SG1. When applying a voltage between the first conductive layer 11 and the second conductive layer 12, a current flowing through the first semiconductor layer 21 varies in accordance with a voltage applied to the first gate electrode SG1. The first transistor 1T acts as, for example, a TFT transistor.

In the semiconductor memory device 110 according to the embodiment, the first resistance change layer 1R and the first transistor 1T, for example, are provided between the first conductive layer 11 and the second conductive layer 12. The second conductive layer 12 is separated from the first conductive layer 11 in a first direction Dr1. Therefore, the first resistance change layer 1R and the transistor 1T are arranged in a vertical direction (the first direction Dr1). Thus, there can be provided a semiconductor memory device in which high integration is achievable.

When applying, for example, a voltage higher than the voltage VT between the first conductive layer 11 and the second conductive layer 12, an excessive current flows through the first resistance change layer 1R in some cases. By providing the first intermediate layer 1M between, for example, the first semiconductor layer 21 and the first resistance change layer 1R, the excessive current can be suppressed. The first intermediate layer 1M includes either of, for example, titanium and tungsten. The first intermediate layer 1M includes a material high in resistance.

The first resistance change layer 1R includes, for example, polysilicon or silicon oxide. It is also possible to suppress the excessive current flowing through the first resistance change layer 1R using, for example, the concentration of polysilicon included in the first resistance change layer 1R.

An example of the material will be described below.

Either of the first conductive layer 11, the second conductive layer 12, and the third conductive layer 13 includes either of a first semiconductor material S1, a first metal material M1, and a first metal compound material MC1.

The first semiconductor material S1 includes polysilicon added with, for example, phosphorus, arsenic, or boron. The first semiconductor material S1 can also include amorphous silicon added with, for example, phosphorus, arsenic, or boron. The first semiconductor material S1 can also include silicon added with, for example, phosphorus, arsenic, or boron. The first semiconductor material S1 can also include silicon-germanium added with, for example, phosphorus, arsenic, or boron. The first semiconductor material S1 can also include germanium added with, for example, phosphorus, arsenic, or boron.

Either of the first metal material M1 and the first metal compound material MC1 includes either of, for example, Pt, Au, Ag, TiAlN, SrRuO, Ru, RuN, Ir, Co, Ni, Ti, TiN, TaN, LaNiO, Al, PtIrOx, PtRhOx, and Rh/TaAlN.

Either of the first conductive layer 11, the second conductive layer 12, and the third conductive layer 13 can also include, for example, carbon, graphene, or carbon nanotube.

Either of the first conductive layer 11, the second conductive layer 12, and the third conductive layer 13 can also include a part including, for example, a metal film having homogenized orientation.

The first metal-containing layer 31 includes either of, for example, Cu, Al, Ni, Ti, Co, Mg, Cr, Mn, Fe, Zn, Sn, In, Pd, Pb, and Bi.

The first resistance change layer 1R includes either of, for example, silicon, polysilicon, amorphous silicon, silicon oxide, silicon nitride, aluminum oxide, hafnium oxide, tantalum oxide, titanium oxide, vanadium oxide, chalcogenide material, tellurium, germanium, antimony, and sulfur. The first resistance change layer 1R can also include a compound including either of, for example, silicon, polysilicon, amorphous silicon, silicon oxide, silicon nitride, aluminum oxide, hafnium oxide, tantalum oxide, titanium oxide, vanadium oxide, chalcogenide material, tellurium, germanium, antimony, and sulfur. The first resistance change layer 1R can also include, for example, carbon.

The first intermediate layer 1M includes either of, for example, tantalum, silicon, and silicon nitride. The first intermediate layer 1M includes either of, for example, tantalum-silicon nitride and tantalum nitride. The first intermediate layer 1M can also include a compound including either of tantalum, silicon, and silicon nitride. The first intermediate layer 1M can also include either of polysilicon, amorphous silicon, silicon, and silicon nitride.

The first semiconductor layer 21 includes the material included in the first semiconductor material S1. The first semiconductor layer 21 can also include either of, for example, TiOx, VOx, HfO, and IGZO.

### Second Embodiment

FIG. 2B is a schematic cross-sectional view illustrating a part of a semiconductor memory device according to a second embodiment.

As shown in FIG. 2B, the semiconductor memory device 120 according to the embodiment is different in the order in which the first semiconductor layer 21, the first intermediate layer 1M, the first resistance change layer 1R, and the first metal-containing layer 31 are arranged in the first direction Dr1, compared to the semiconductor memory device 110.

The details will hereinafter be described.

The semiconductor memory device 120 according to the embodiment includes the first conductive layer 11, the second conductive layer 12, the first metal-containing layer 31, the first resistance change layer 1R, the first semiconductor layer 21, and the third conductive layer 13.

The first conductive layer 11 includes the first region 11r. The second conductive layer 12 is provided so as to be separated from the first conductive layer 11 in the first direction Dr1. The first metal-containing layer 31 is provided between the first region 11r and the second conductive layer 12. The first resistance change layer 1R is provided between the first metal-containing layer 31 and the first region 11r. The first semiconductor layer 21 is provided between the first resistance change layer 1R and the first region 11r. The third conductive layer 13 is arranged with the first semiconductor layer 21 in the second direction Dr2.

It is also possible for the semiconductor memory device 120 according to the embodiment to further include the first intermediate layer 1M provided between the first semiconductor layer 21 and the first resistance change layer 1R.

The first conductive layer 11 extends in, for example, the second direction Dr2. The second conductive layer 12 extends in, for example, the third direction Dr3. The third conductive layer 13 extends in, for example, the third direction Dr3.

### Third Embodiment

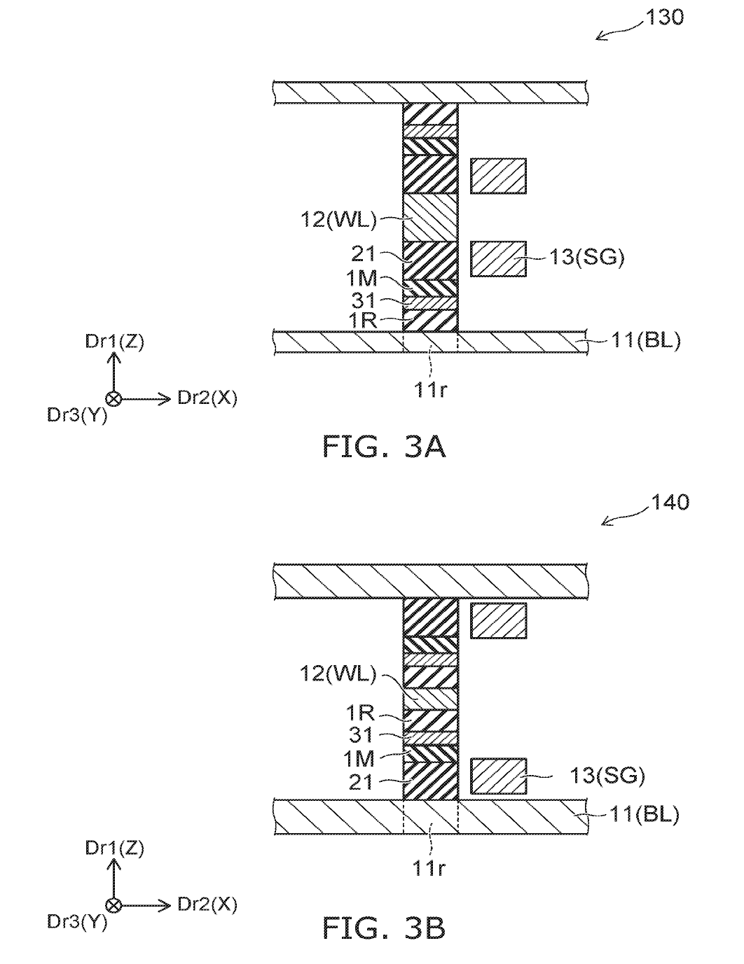

FIG. 3A is a schematic cross-sectional view illustrating a part of a semiconductor memory device according to a third embodiment.

As shown in FIG. 3A, the semiconductor memory device 130 according to the embodiment is different in the order in which the first semiconductor layer 21, the first intermediate layer 1M, the first resistance change layer 1R, and the first metal-containing layer 31 are arranged in the first direction Dr1, compared to the semiconductor memory device 110.

The semiconductor memory device 130 according to the embodiment includes the first conductive layer 11, the second conductive layer 12, the first semiconductor layer 21, the third conductive layer 13, the first metal-containing layer 31, and the first resistance change layer 1R. The first conductive layer 11 includes the first region 11r. The second conductive layer 12 is provided so as to be separated from the first conductive layer 11 in the first direction Dr1. The first semiconductor layer 21 is provided between the first region 11r and the second conductive layer 12. The third conductive layer 13 is arranged with the first semiconductor layer 21 in the second direction Dr2. The first metal-containing layer 31 is provided between the first semiconductor layer 21 and the first region 11r. The first resistance change layer 1R is provided between the first metal-containing layer 31 and the first region 11r.

It is also possible for the semiconductor memory device 130 according to the embodiment to further include the first intermediate layer 1M provided between the first semiconductor layer 21 and the first metal-containing layer 31.

The first conductive layer 11 extends in the second direction Dr2. The first conductive layer 12 extends in the third direction Dr3. The third conductive layer 13 extends in the third direction Dr3.

### Fourth Embodiment

FIG. 3B is a schematic cross-sectional view illustrating a part of a semiconductor memory device according to a fourth embodiment.

As shown in FIG. 3B, the semiconductor memory device 140 according to the embodiment is different in the order in which the first semiconductor layer 21, the first intermediate layer 1M, the first resistance change layer 1R, and the first metal-containing layer 31 are arranged in the first direction Dr1, compared to the semiconductor memory device 110.

The semiconductor memory device 140 according to the embodiment includes the first conductive layer 11, the second conductive layer 12, the first resistance change layer 1R, the first metal-containing layer 31, the first semiconductor layer 21, and the third conductive layer 13. The first conductive layer 11 includes the first region 11r. The second conductive layer 12 is provided so as to be separated from the first conductive layer 11 in the first direction Dr1. The first resistance change layer 1R is provided between the first region 11r and the second conductive layer 12. The first metal-containing layer 31 is provided between the first resistance change layer 1R and the first region 11r. The first semiconductor layer 21 is provided between the first metal-containing layer 31 and the first region 11r. The third conductive layer 13 is arranged with the first semiconductor layer 21 in the second direction Dr2.

It is also possible for the semiconductor memory device 140 according to the embodiment to further include the first intermediate layer 1M provided between the first semiconductor layer 21 and the first metal-containing layer 31.

The first conductive layer 11 extends in the second direction Dr2. The second conductive layer 12 extends in the third direction Dr3. The third conductive layer 13 extends in the third direction Dr3.

### Fifth Embodiment

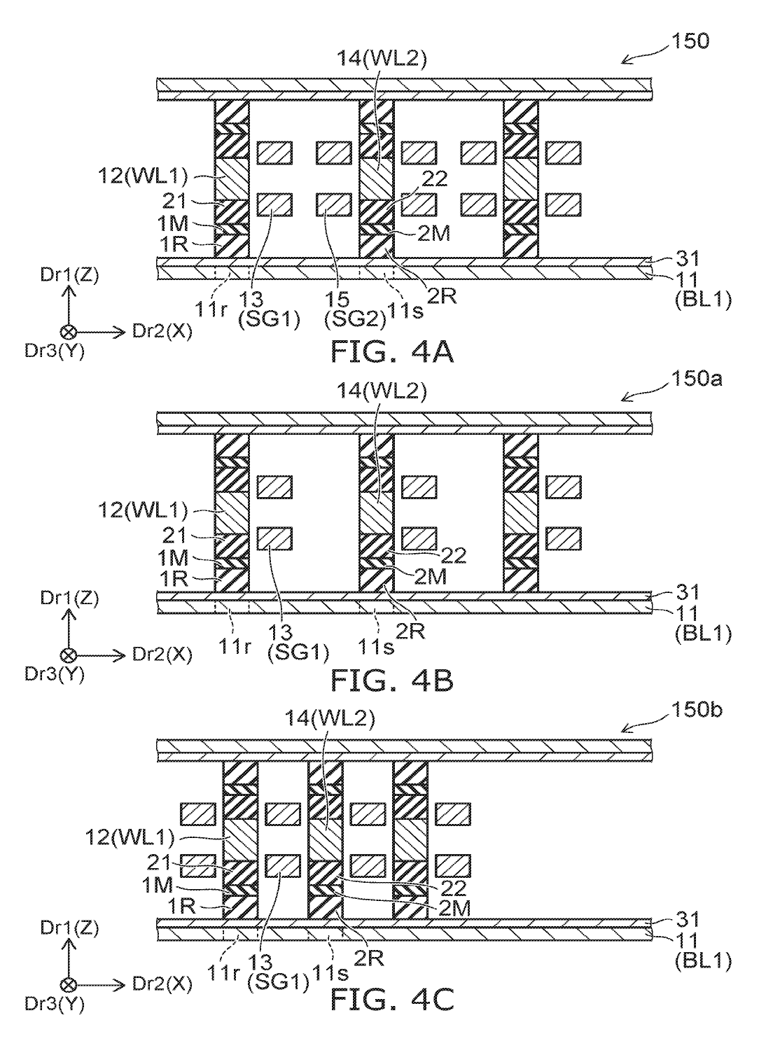

FIG. 4A is a schematic cross-sectional view illustrating a part of a semiconductor memory device according to a fifth embodiment.

As shown in FIG. 4A, the semiconductor memory device 150 according to the embodiment further includes a fourth conductive layer 14, a fifth conductive layer 15, a second semiconductor layer 22, and a second resistance change layer 2R compared to the semiconductor memory device 110 according to the first embodiment.

In the semiconductor memory device 150 according to the embodiment, there is provided an array structure having a plurality of first blocks BLK1 arranged in the second direction Dr2. Gate electrodes are respectively disposed on both sides of a second TFT channel (the second semiconductor layer 22).

The first conductive layer 11 further includes a second region 11s. The fourth conductive layer 14 is arranged with the second conductive layer 12 in the second direction Dr2. The second semiconductor layer 22 is disposed between the fourth conductive layer 14 and the second region 11s. The fifth conductive layer 15 is disposed between the third conductive layer 13 and the second semiconductor layer 22. The second resistance change layer 2R is disposed between the second semiconductor layer 22 and the second region 11s. The first metal-containing layer 31 is further disposed between the second resistance change layer 2R and the second region 11s. It is also possible for a second intermediate layer 2M to be further disposed between the second semiconductor layer 22 and the second resistance change layer 2R.

The fourth conductive layer 14 extends in, for example, the third direction Dr3. The fifth conductive layer 15 extends in, for example, the third direction Dr3. The first metal-containing layer 31 can also extend in the second direction Dr2.

The fifth conductive layer 15 is, for example, a second gate electrode SG2. When applying a voltage between the first conductive layer 11 and the fourth conductive layer 14, a current flowing through the second semiconductor layer 22 varies in accordance with a voltage applied to the second gate electrode SG2. The second semiconductor layer 22 and the second gate electrode SG2 act as a TFT transistor.

FIG. 4B is a schematic cross-sectional view illustrating a part of another example of the semiconductor memory device according to the fifth embodiment.

As shown in FIG. 4B, in the semiconductor memory device 150a according to the embodiment, the plurality of first blocks BLK1 are disposed in the second direction Dr2. In the semiconductor memory device 150a according to the embodiment, the fifth conductive layer 15 is not provided.

FIG. 4C is a schematic cross-sectional view illustrating a part of another example of the semiconductor memory device according to the fifth embodiment.

As shown in FIG. 4C, the semiconductor memory device 150b according to the embodiment is not provided with the fifth conductive layer 15. The distance between the first semiconductor layer 21 and the second semiconductor layer 22 of the semiconductor memory device 150b is shorter than the distance between the first semiconductor layer 21 and the second semiconductor 22 of the semiconductor memory device 150. Thus, in the case of applying a voltage between the first conductive layer 11 and the second conductive layer 12, a current flowing through the first semiconductor layer 21 varies, and at the same time, a current flowing through the second semiconductor layer 22 also varies, in accordance with a voltage applied to the third conductive layer 13. The first TFT channel (the first semiconductor layer 21) shares the first gate electrode SG1 (the third conductive layer 13) with the second TFT channel (the second semiconductor layer 22).

### Sixth Embodiment

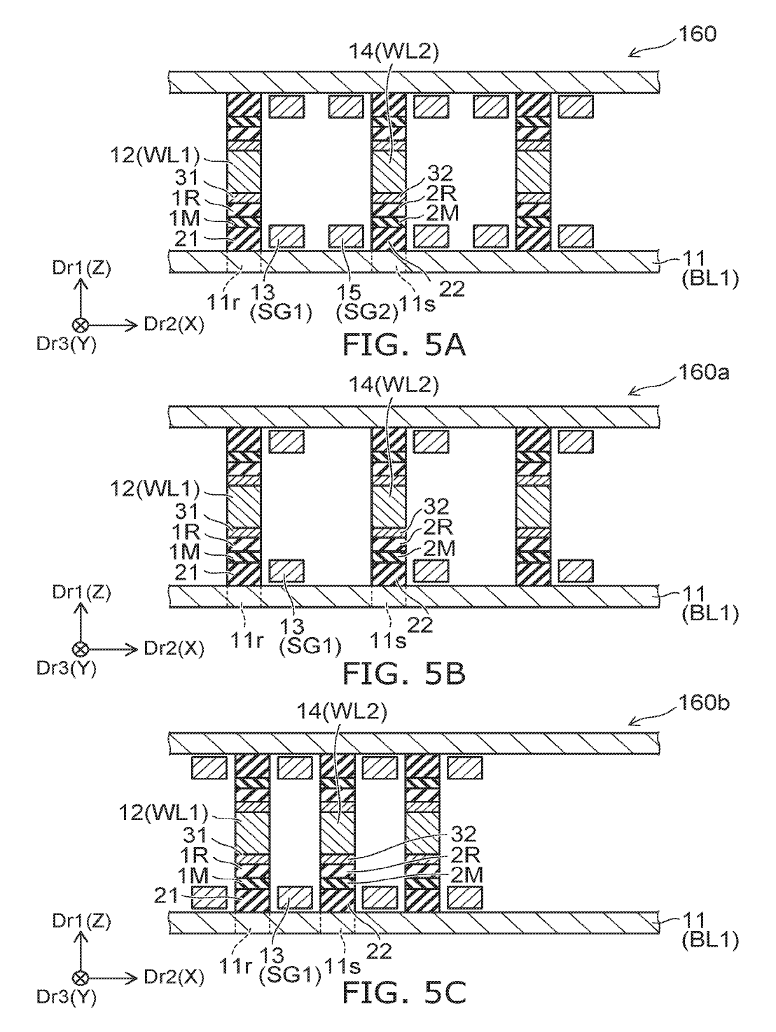

FIG. 5A is a schematic cross-sectional view illustrating a part of a semiconductor memory device according to a sixth embodiment.

As shown in FIG. 5A, the semiconductor memory device 160 according to the embodiment further includes the fourth conductive layer 14, the fifth conductive layer 15, the second semiconductor layer 22, the second resistance change layer 2R, and a second metal-containing layer 32 compared to the semiconductor memory device 120 according to the second embodiment.

The first conductive layer 11 further includes a second region 11s. The fourth conductive layer 14 is arranged with the second conductive layer 12 in the second direction Dr2. The second metal-containing layer 32 is disposed between the fourth conductive layer 14 and the second region 11s. The second resistance change layer 2R is disposed between the second metal-containing layer 32 and the second region 11s. The second semiconductor layer 22 is disposed between the second resistance change layer 2R and the second region 11s. The fifth conductive layer 15 is disposed between the third conductive layer 13 and the second semiconductor layer 22.

The fourth conductive layer 14 extends in, for example, the third direction Dr3. The fifth conductive layer 15 extends in, for example, the third direction Dr3.

FIG. 5B is a schematic cross-sectional view illustrating a part of another example of the semiconductor memory device according to the sixth embodiment.

As shown in FIG. 5B, in the semiconductor memory device 160a according to the embodiment, the fifth conductive layer 15 is not provided.

FIG. 5C is a schematic cross-sectional view illustrating a part of another example of the semiconductor memory device according to the sixth embodiment.

As shown in FIG. 5C, the semiconductor memory device 160b according to the embodiment is not provided with the fifth conductive layer 15. In the case of applying a voltage between the first conductive layer 11 and the second conductive layer 12, a current flowing through the first semiconductor layer 21 varies, and at the same time, a current flowing through the second semiconductor layer 22 also varies, in accordance with a voltage applied to the third conductive layer 13.

### Seventh Embodiment

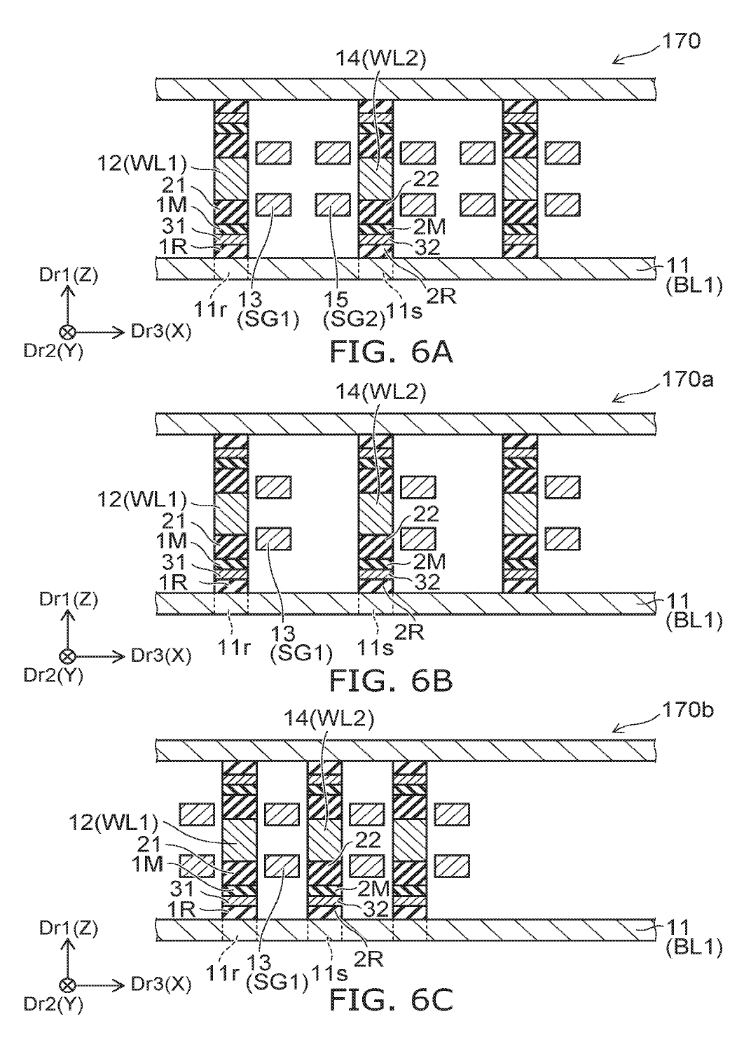

FIG. 6A is a schematic cross-sectional view illustrating a part of a semiconductor memory device according to a seventh embodiment.

As shown in FIG. 6A, the semiconductor memory device 170 according to the embodiment further includes the fourth conductive layer 14, the fifth conductive layer 15, the second semiconductor layer 22, the second resistance change layer 2R, and the second metal-containing layer 32 compared to the semiconductor memory device 130 according to the third embodiment.

The first conductive layer 11 further includes the second region 11s. The fourth conductive layer 14 is arranged with the second conductive layer 12 in the second direction Dr2. The second semiconductor layer 22 is disposed between the fourth conductive layer 14 and the second region 11s. The second metal-containing layer 32 is disposed between the second semiconductor layer 22 and the second region 11s. The second resistance change layer 2R is disposed between the second metal-containing layer 32 and the second region 11s. The fifth conductive layer 15 is provided between the third conductive layer 13 and the second semiconductor layer 22.

The fourth conductive layer 14 extends in, for example, the third direction Dr3. The fifth conductive layer 15 extends in, for example, the third direction Dr3.

FIG. 6B is a schematic cross-sectional view illustrating a part of another example of the semiconductor memory device according to the seventh embodiment.

As shown in FIG. 6B, the semiconductor memory device 170a according to the embodiment is not provided with the fifth conductive layer 15.

FIG. 6C is a schematic cross-sectional view illustrating a part of another example of the semiconductor memory device according to the seventh embodiment.

As shown in FIG. 6C, the semiconductor memory device 170b according to the embodiment is not provided with the fifth conductive layer 15.

### Eighth Embodiment

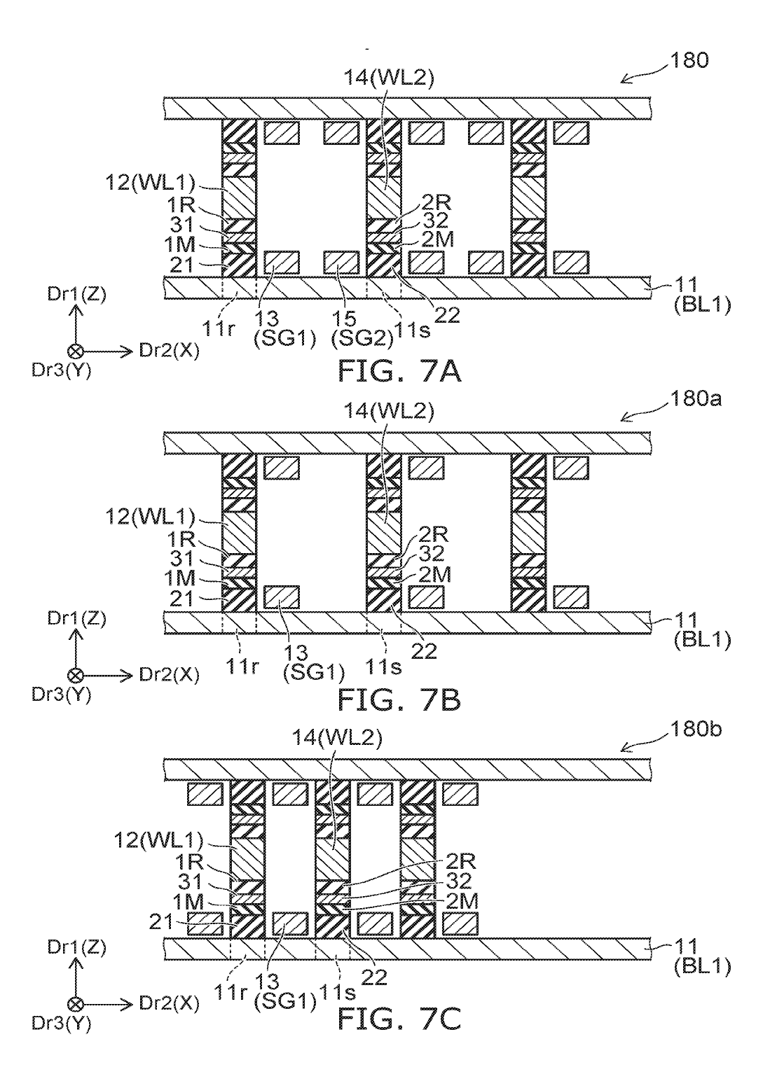

FIG. 7A is a schematic cross-sectional view illustrating a part of a semiconductor memory device according to an eighth embodiment.

As shown in FIG. 7A, the semiconductor memory device 180 according to the embodiment further includes the fourth conductive layer 14, the second semiconductor layer 22, the fifth conductive layer 15, the second resistance change layer 2R, and the second metal-containing layer 32 compared to the semiconductor memory device 140 according to the fourth embodiment.

The first conductive layer 11 further includes the second region 11s. The fourth conductive layer 14 is arranged with the second conductive layer 12 in the second direction Dr2. The second resistance change layer 2R is disposed between the fourth conductive layer 14 and the second region 11s. The second metal-containing layer 32 is disposed between the second resistance change layer 2R and the second region 11s. The second semiconductor layer 22 is disposed between the second metal-containing layer 32 and the second region 11s. The fifth conductive layer 15 is disposed between the third conductive layer 13 and the second semiconductor layer 22.

The fourth conductive layer 14 extends in, for example, the third direction Dr3. The fifth conductive layer 15 extends in, for example, the third direction Dr3.

FIG. 7B is a schematic cross-sectional view illustrating a part of another example of the semiconductor memory device according to the eighth embodiment.

As shown in FIG. 7B, the semiconductor memory device 180a according to the embodiment is not provided with the fifth conductive layer 15.

FIG. 7C is a schematic cross-sectional view illustrating a part of another example of the semiconductor memory device according to the eighth embodiment.

As shown in FIG. 7C, the semiconductor memory device 180b according to the embodiment is not provided with the fifth conductive layer 15.

### Ninth Embodiment

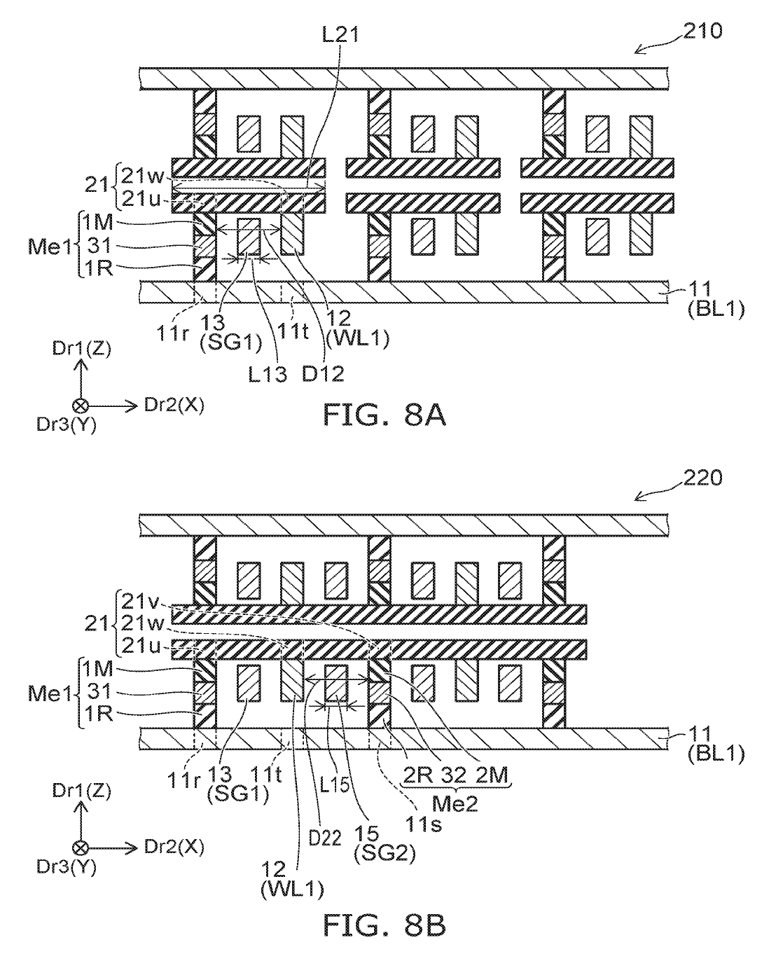

FIG. 8A is a schematic cross-sectional view illustrating a part of a semiconductor memory device according to a ninth embodiment.

As shown in FIG. 8A, in the semiconductor memory device 210 according to the embodiment, the first TFT channel (the first semiconductor layer 21) extends in the second direction Dr2.

The semiconductor memory device 210 according to the embodiment includes the first conductive layer 11, the first semiconductor layer 21, the first resistance change layer 1R, the first metal-containing layer 31, the second conductive layer 12, and the third conductive layer 13.

The first conductive layer 11 extends in the second direction Dr2. The first conductive layer 11 includes the first region 11r and a third region 11t. The third region 11t is separated from the first region 11r in the second direction Dr2.

The first semiconductor layer 21 is provided so as to be separated from the first conductive layer 11 in the first direction Dr1. The first semiconductor layer 21 extends in the second direction Dr2. The first semiconductor layer 21 includes a fourth region 21u and a sixth region 21w. The sixth region 21w is separated from the fourth region 21u in the second direction Dr2.

The first metal-containing layer 31 is provided between the fourth region 21u and the first region 11r. The first resistance change layer 1R is provided between the first metal-containing layer 31 and the first region 11r. The second conductive layer 12 is provided between the sixth region 21w and the third region lit. The third conductive layer 13 is provided between the first conductive layer 11 and the first semiconductor layer 21. The second conductive layer 12 is arranged with the third conductive layer 13 in the second direction Dr2.

The length L13 along the second direction Dr2 of the third conductive layer 13 is shorter than the length L21 along the second direction Dr2 of the first semiconductor layer 21.

It is also possible for the semiconductor memory device 210 according to the embodiment to further include the first intermediate layer 1M provided between the fourth region 21u and the first metal-containing layer 31.

A first memory element (a first memory cell Me1) includes, for example, the first resistance change layer 1R, the first metal-containing layer 31, and the first intermediate layer 1M.

The length L13 along the second direction Dr2 of the third conductive layer is shorter than a distance D12 between the first memory cell Me1 and the second conductive layer 12.

FIG. 8B is a schematic cross-sectional view illustrating a part of another example of the semiconductor memory device according to the ninth embodiment.

As shown in FIG. 8B, the semiconductor memory device 220 according to the embodiment further includes the fifth conductive layer 15, the second resistance change layer 2R, and the second metal-containing layer 32 compared to the semiconductor memory device 210.

The first semiconductor layer 21 further includes a fifth region 21v. The sixth region 21w is disposed between the fourth region 21u and the fifth region 21v. The first conductive layer 11 further includes the second region 11s. The third region 11t is disposed between the fourth region 21u and the second region 11s.

The second metal-containing layer 32 is provided between the fifth region 21v and the second region 11s. The second resistance change layer 2R is provided between the second metal-containing layer 32 and the second region 11s. The fifth conductive layer 15 is provided between the first conductive layer 11 and the first semiconductor layer 21. The fifth conductive layer 15 is arranged with the third conductive layer 13 in the second direction Dr2.

It is also possible for the semiconductor memory device 220 according to the embodiment to further include the second intermediate layer 2M provided between the fifth region 21v and the second region 11s.

A second memory element (a second memory cell Me2) includes, for example, the second resistance change layer 2R, the second metal-containing layer 32, and the second intermediate layer 2M.

The length L15 along the second direction Dr2 of the fifth conductive layer is shorter than a distance D22 between the second memory cell Me2 and the second conductive layer 12.

### Tenth Embodiment

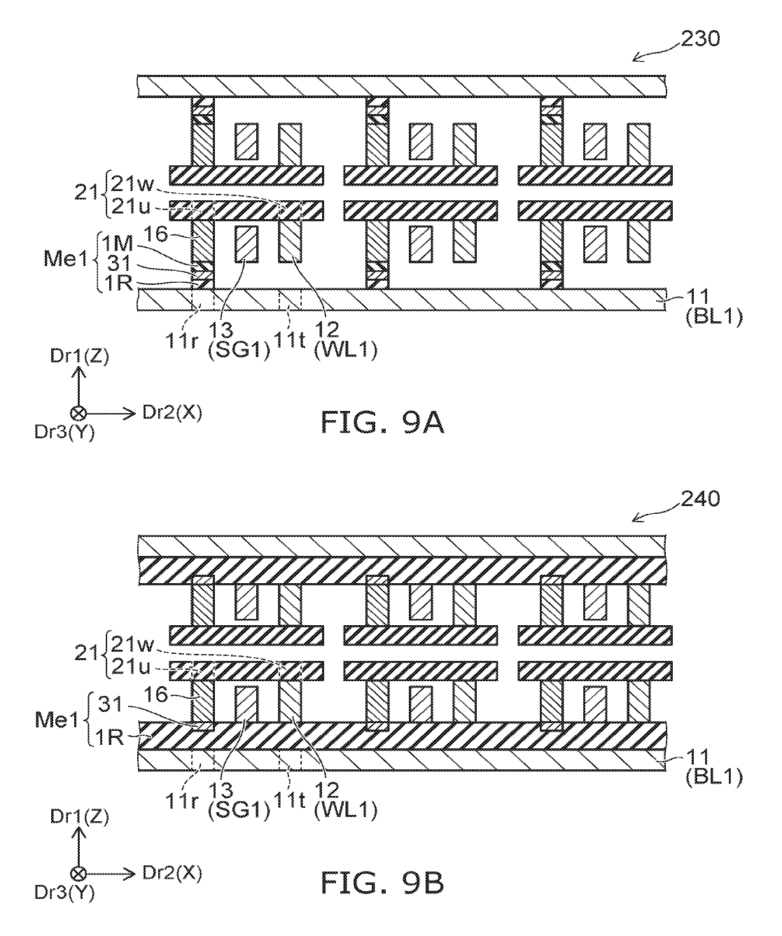

FIG. 9A is a schematic cross-sectional view illustrating a part of a semiconductor memory device according to a tenth embodiment.

As shown in FIG. 9A, the semiconductor memory device 230 according to the embodiment further includes a sixth conductive layer 16 compared to the semiconductor memory device 210. The sixth conductive layer 16 is provided between the fourth region 21u and the first intermediate layer 1M. The sixth conductive layer 16 is arranged with the second conductive layer 12 in the second direction Dr2.

The sixth conductive layer 16 includes the material included in the second conductive layer 12. The sixth conductive layer 16 includes the material included in the third conductive layer 13. The second conductive layer 12 includes the material included in the third conductive layer 13.

FIG. 9B is a schematic cross-sectional view illustrating a part of another example of the semiconductor memory device according to the tenth embodiment.

As shown in FIG. 9B, the semiconductor memory device 240 according to the embodiment differs in the configuration such as the first resistance change layer 1R, the first metal-containing layer 31, and so on compared to the semiconductor memory device 230.

The semiconductor memory device 240 according to the embodiment includes the first conductive layer 11, the first semiconductor layer 21, the first resistance change layer 1R, the first metal-containing layer 31, the second conductive layer 12, the third conductive layer 13, and the sixth conductive layer 16.

The first resistance change layer 1R is further provided so as to overlap the first conductive layer 11 in the first direction Dr1. The first metal-containing layer 31 overlaps a part of the first resistance change layer 1R in the second direction Dr2.

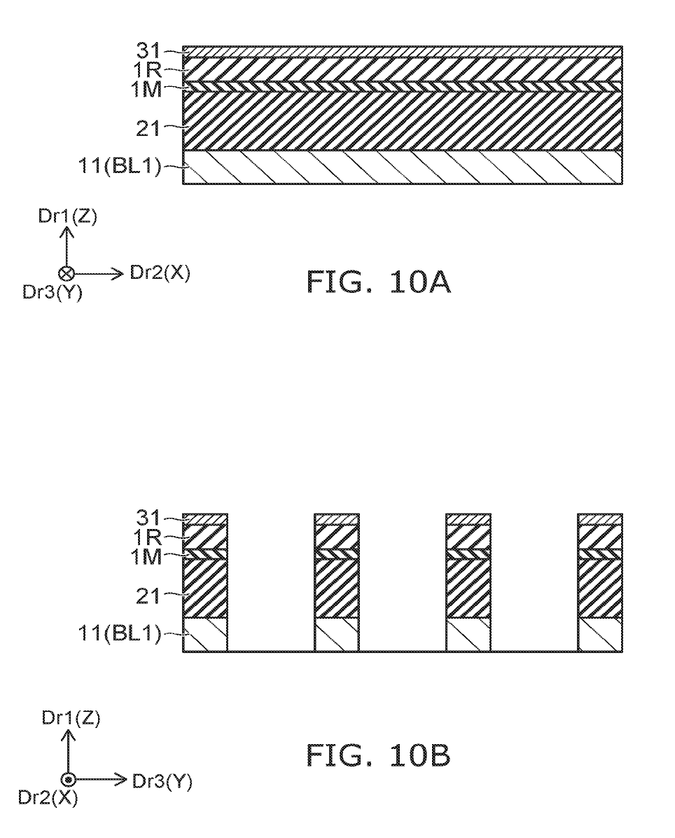

FIG. 10A and FIG. 10B are schematic cross-sectional views illustrating a method of manufacturing the semiconductor memory device according to the sixth embodiment.

As shown in FIG. 10A and FIG. 10B, the first semiconductor layer 21 is formed on the first conductive layer 11. The first intermediate layer 1M is formed on the first semiconductor layer 21. The first resistance change layer 1R is formed on the first intermediate layer 1M. The first metal-containing layer 31 is formed on the first resistance change layer 1R.

A part of the first metal-containing layer 31 is removed to thereby separate the first metal-containing layer 31 in the third direction Dr3. Similarly to the formation of the first metal-containing layer 31, the first resistance change layer 1R is separated in the third direction Dr3. The first intermediated layer 1M is separated in the third direction Dr3. The first semiconductor layer 21 is separated in the third direction Dr3. The first conductive layer 11 is separated in the third direction Dr3. In other words, line-and-space processing is performed on the stacked body of the first conductive layer 11 through the first metal-containing layer 31 in the third direction Dr3.

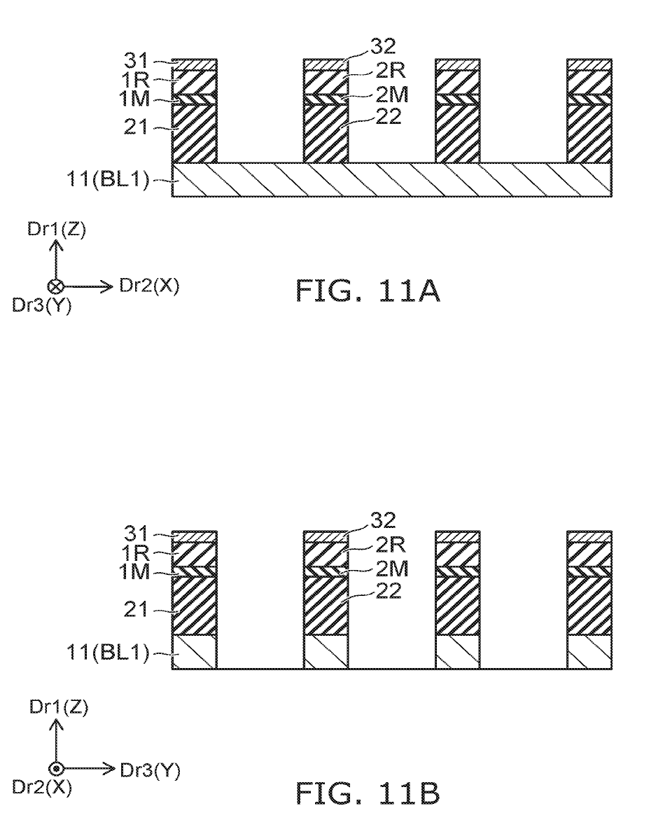

FIG. 11A and FIG. 11B are schematic cross-sectional views illustrating the method of manufacturing the semiconductor memory device according to the sixth embodiment.

As shown in FIG. 11A and FIG. 11B, the first metal-containing layer 31 through the first semiconductor layer 21 are separated in the second direction Dr2. Thus, the second metal-containing layer 32, the second resistance change layer 2R, the second intermediate layer 2M, and the second semiconductor layer 22 are formed. The first conductive layer 11 is not separated in the second direction Dr2. The line-and-space processing is performed on the stacked body of the first semiconductor layer 21 through the first metal-containing layer 31 in the second direction Dr2.

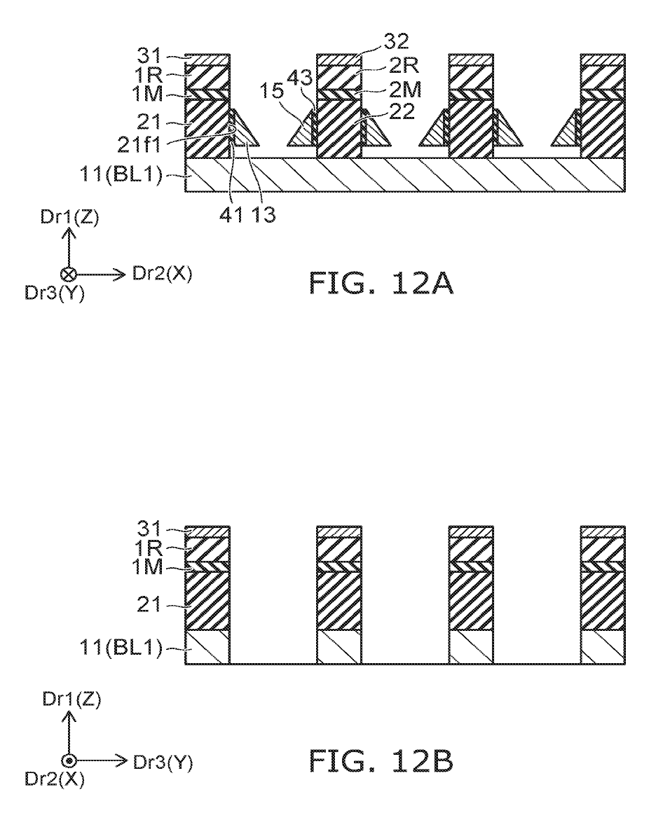

FIG. 12A and FIG. 12B are schematic cross-sectional views illustrating the method of manufacturing the semiconductor memory device according to the sixth embodiment.

As shown in FIG. 12A and FIG. 12B, an oxide film including, for example, silicon oxide is deposited on a surface of the stacked body of the second semiconductor layer 21 through the first metal-containing layer 31 and a surface of the first conductive layer 11. The gate electrode (the third conductive layer 13) is formed on the oxide film. Subsequently, due to a spacer process, a gate insulating layer 41 remains between the gate electrode and the first semiconductor layer 21. Similarly, the fifth conductive layer 15 is formed. Between the fifth conductive layer 15 and the second semiconductor layer 22, there remains a gate insulating layer 43.

The shape in a plane crossing the third direction Dr3 of the third conductive layer 13 is a roughly triangular shape. Similarly to the third conductive layer 13, the shape in the plane crossing the third direction Dr3 of the fifth conductive layer 15 is a roughly triangular shape.

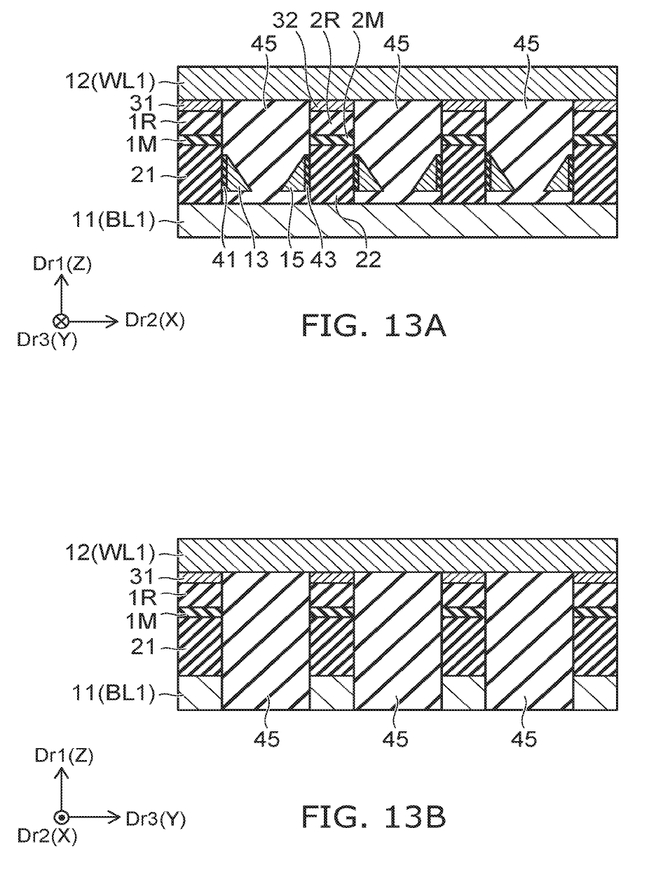

FIG. 13A and FIG. 13B are schematic cross-sectional views illustrating the method of manufacturing the semiconductor memory device according to the sixth embodiment.

As shown in FIG. 13A and FIG. 13B, the insulating material is deposited on the first conductive layer 11 to form an interline insulating layer (an insulating layer 45). The insulating layer 45 and the first metal-containing layer 31 are planarized. Tungsten, for example, is deposited on the insulating layer 45 and the first metal-containing layer 31 to form the first word line WL (the second conductive layer 12).

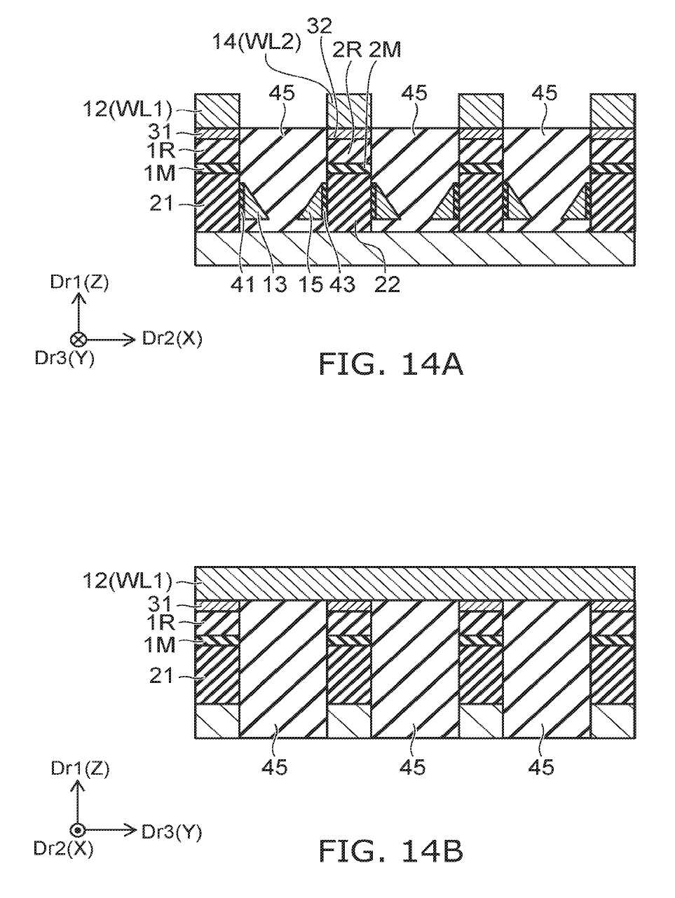

FIG. 14A and FIG. 14B are schematic cross-sectional views illustrating the method of manufacturing the semiconductor memory device according to the sixth embodiment.

As shown in FIG. 14A and FIG. 14B, a part of the first word line WL (the second conductive layer 12) is removed. Thus, the first word line WL (the second conductive layer 12) is separated in the second direction Dr2, and thus, a second word line WL2 (the fourth conductive layer 14) is formed.

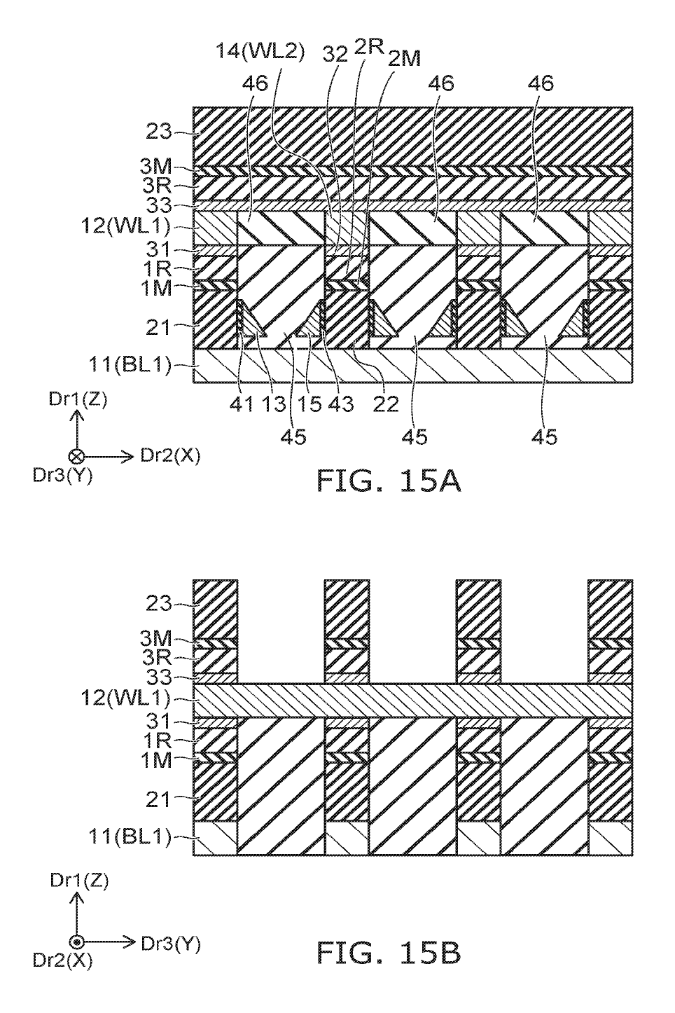

FIG. 15A and FIG. 15B are schematic cross-sectional views illustrating the method of manufacturing the semiconductor memory device according to the sixth embodiment.

As shown in FIG. 15A and FIG. 15B, the insulating material is deposited on the insulating layer 45 to form an insulating layer 46. A third metal-containing layer 33 is formed on a part of the insulating layer 46, a part of the second conductive layer 12, and a part of the fourth conductive layer 14. The third metal-containing layer 33 is arranged with the first conductive layer 11 in the first direction Dr1. A third resistance change layer 3R is formed on the third metal-containing layer 33. A third intermediate layer 3M is formed on the third resistance change layer 3R. A third semiconductor layer 23 is formed on the third intermediate layer 3M.

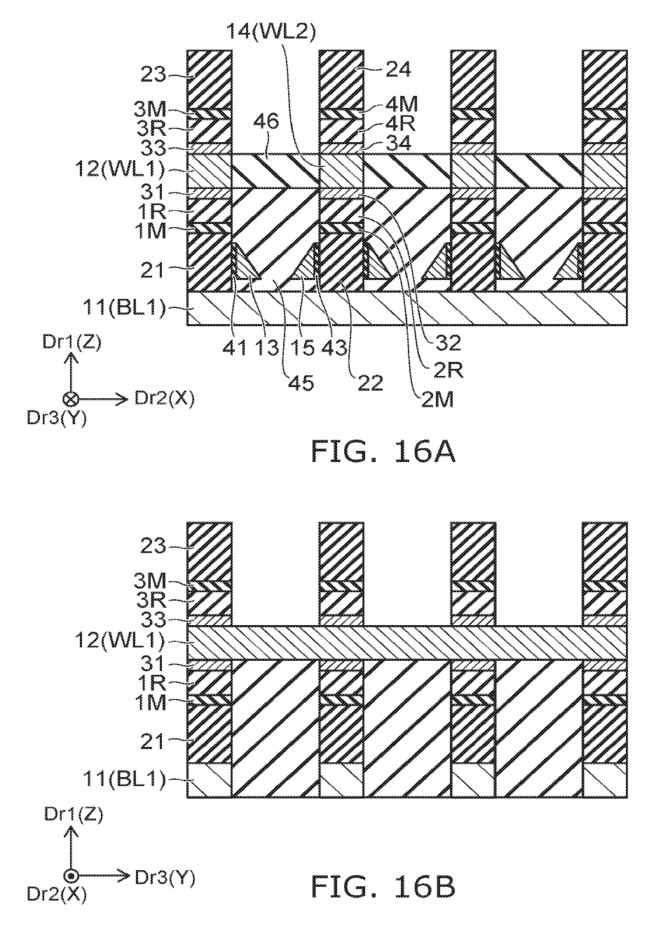

FIG. 16A and FIG. 16B are schematic cross-sectional views illustrating the method of manufacturing the semiconductor memory device according to the sixth embodiment.

As shown in FIG. 16A and FIG. 16B, a stacked body of the third semiconductor layer 23 through the third metal-containing layer 33 is separated in the second direction Dr2. Thus, a fourth semiconductor layer 24, a fourth intermediate layer 4M, a fourth resistance change layer 4R, and a fourth metal-containing layer 34 are formed. Specifically, the stacked body of the third semiconductor layer 23 through the third metal-containing layer 33 is formed so as to have a pillar shape. Similarly, the stacked body of the fourth semiconductor layer 24 through the fourth metal-containing layer 34 is formed so as to have a pillar shape.

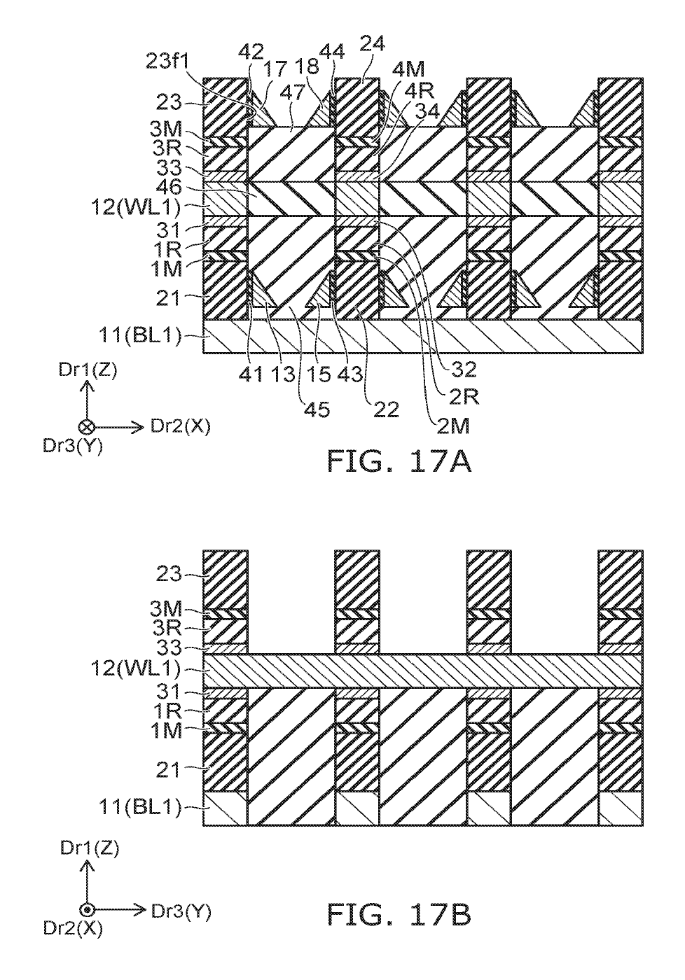

FIG. 17A and FIG. 17B are schematic cross-sectional views illustrating the method of manufacturing the semiconductor memory device according to the sixth embodiment.

As shown in FIG. 17A and FIG. 17B, the insulating material is deposited on the insulating layer 46 to form an insulating layer 47. Similarly to the formation of the third conductive layer 13, the gate insulating layer 41, the fifth conductive layer 15, and the gate insulating layer 43, a gate insulating layer 42, a seventh conductive layer 17, a gate insulating layer 44, and an eighth conductive layer 18 are formed on the insulating layer 47.

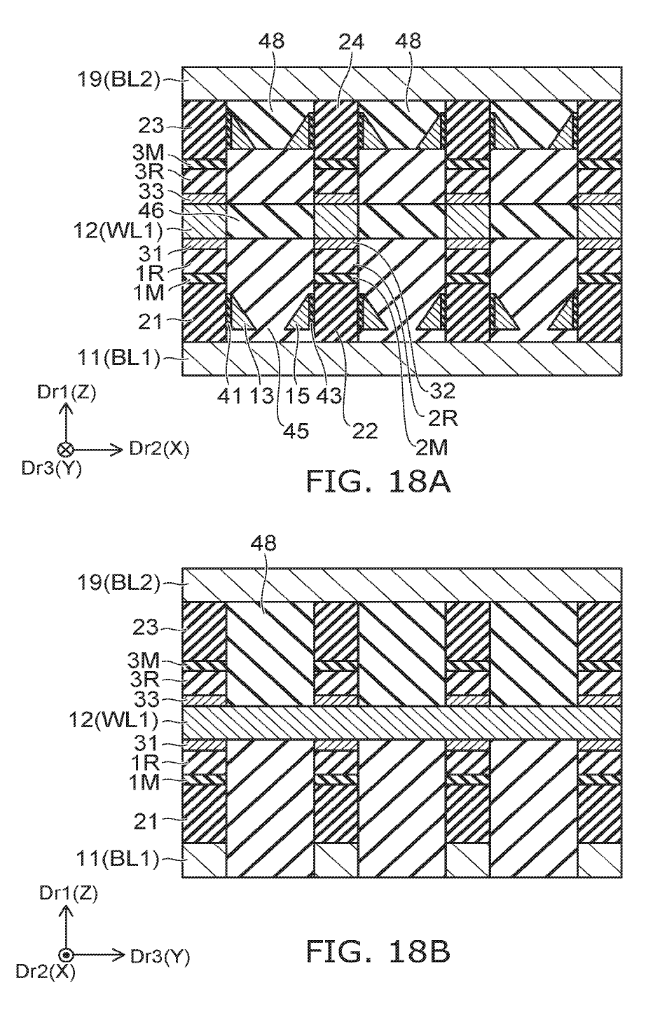

FIG. 18A and FIG. 18B are schematic cross-sectional views illustrating the method of manufacturing the semiconductor memory device according to the sixth embodiment.

As shown in FIG. 18A and FIG. 18B, an insulating layer 48 is formed on the insulating layer 47. A second bit line BL2 (a ninth conductive layer 19) is formed on the third semiconductor layer 23, the fourth semiconductor layer 24, and the insulating layer 48.

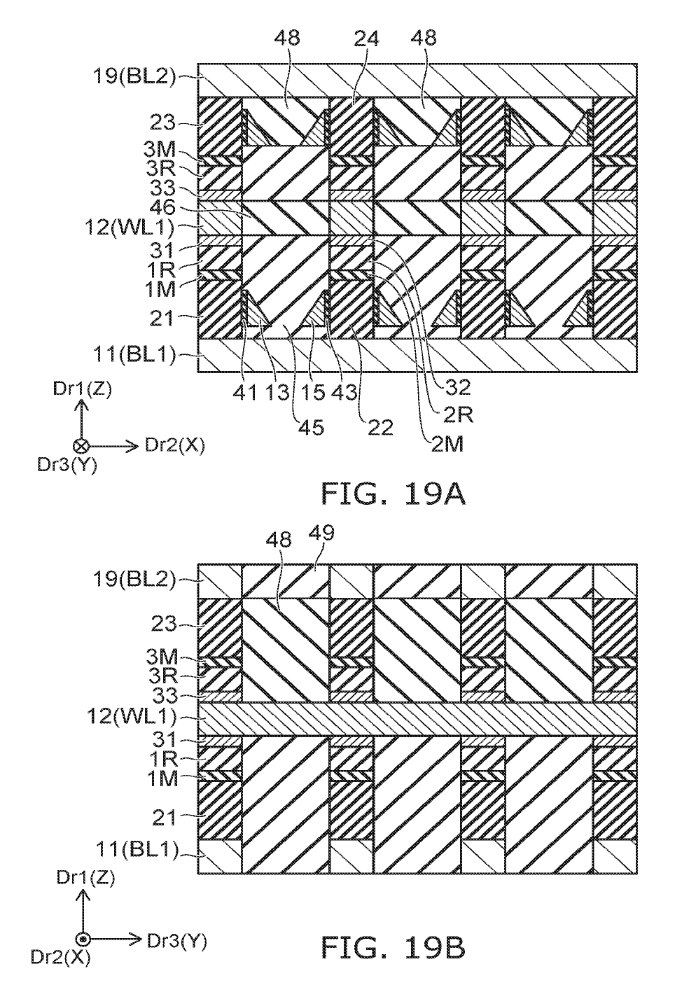

FIG. 19A and FIG. 19B are schematic cross-sectional views illustrating the method of manufacturing the semiconductor memory device according to the sixth embodiment.

As shown in FIG. 19A and FIG. 19B, a part of the second bit line BL2 (the ninth conductive layer 19) is removed. Thus, the second bit line BL2 (the ninth conductive layer 19) is separated in the third direction Dr3. The second bit line BL2 (the ninth conductive layer 19) extends in the second direction Dr2. An interline insulating layer (an insulating layer 49) is formed on the insulating layer 48. The second bit line BL2 (the ninth conductive layer 19) and the interline insulating layer (the insulating layer 49) are planarized.

According to the embodiment, there can be provided a semiconductor memory device in which high integration is achievable.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a first conductive layer;
a second conductive layer provided to be separated from the first conductive layer in a first direction;
a first semiconductor layer provided between the first conductive layer and the second conductive layer;
a third conductive layer arranged with the first semiconductor layer in a direction crossing the first direction;
a first resistance change layer provided between the first semiconductor layer and the first conductive layer; and
a first metal-containing layer provided between the first resistance change layer and the first conductive layer,
the first conductive layer extending in a second direction crossing the first direction,
the second conductive layer extending in a third direction crossing the first direction and crossing the second direction, and
the third conductive layer extending in a direction crossing the first direction.

2. The device according to claim 1, wherein
the third conductive layer extends in the third direction.

3. The device according to claim 1, wherein
the third conductive layer extends in the second direction.

4. The device according to claim 2, wherein
the first metal-containing layer extends in the second direction.

5. The device according to claim 1, further comprising:
a first intermediate layer provided between the first semiconductor layer and the first resistance change layer.

6. The device according to claim 1, wherein
either of the first conductive layer, the second conductive layer, and the third conductive layer includes one of silicon including one of phosphorus, arsenic, and boron, silicon-germanium including one of phosphorus, arsenic, and boron, and germanium including one of phosphorus, arsenic, and boron,
either of the first conductive layer, the second conductive layer, and the third conductive layer includes either of Pt, Au, Ag, TiAlN, SrRuO, Ru, RuN, Ir, Co, Ni, Ti, TiN, TaN, LaNiO, Al, PtIrOx, PtRhOx, Rh, and TaAlN, or
either of the first conductive layer, the second conductive layer, and the third conductive layer includes either of carbon, graphene, and carbon nanotube.

7. The device according to claim 1, wherein
the first semiconductor layer includes one of silicon including one of phosphorus, arsenic, and boron, silicon-germanium including one of phosphorus, arsenic, and boron, and germanium including one of phosphorus, arsenic, and boron, or
the first semiconductor layer includes either of TiOx, VOx, HfO, and IGZO.

8. The device according to claim 1, wherein
The first resistance change layer includes either of silicon, polysilicon, amorphous silicon, silicon oxide, silicon nitride, aluminum oxide, hafnium oxide, tantalum oxide, titanium oxide, vanadium oxide, chalcogenide material, tellurium, germanium, antimony, sulfur, and carbon, and
the first metal-containing layer includes either of Cu, Al, Ni, Ti, Co, Mg, Cr, Mn, Fe, Zn, Sn, In, Pd, Pb, and Bi.

9. The device according to claim 5, wherein
the first intermediate layer includes either of tantalum, silicon, silicon nitride, tantalum-silicon nitride, tantalum nitride, polysilicon, and amorphous silicon.

10. A semiconductor memory device comprising:
a first conductive layer;
a second conductive layer provided to be separated from the first conductive layer in a first direction;
a first semiconductor layer provided between the first conductive layer and the second conductive layer;
a third conductive layer arranged with the first semiconductor layer in a direction crossing the first direction;
a first metal-containing layer provided between the first semiconductor layer and the first conductive layer; and
a first resistance change layer provided between the first metal-containing layer and the first conductive layer,
the first conductive layer extending in a second direction crossing the first direction,
the second conductive layer extending in a third direction crossing the first direction and crossing the second direction, and
the third conductive layer extending in a direction crossing the first direction.

11. The device according to claim 10, wherein
the third conductive layer extends in the third direction.

12. The device according to claim 10, wherein
the third conductive layer extends in the second direction.

13. The device according to claim 10, further comprising:
a first intermediate layer provided between the first semiconductor layer and the first metal-containing layer.

14. The device according to claim 1, further comprising:
a fourth conductive layer arranged with the second conductive layer in the second direction, and extending in the third direction;
a second semiconductor layer provided between the fourth conductive layer and the first conductive layer;
a fifth conductive layer disposed between the third conductive layer and the second semiconductor layer, and extending in a direction crossing the first direction; and
a second resistance change layer provided between the second semiconductor layer and the first conductive layer,
the first metal-containing layer being further disposed between the second resistance change layer and the first conductive layer.

15. The device according to claim 14, wherein
the fifth conductive layer extends in the third direction.

16. The device according to claim 14, wherein
the fifth conductive layer extends in the second direction.

17. The device according to claim 14, wherein
the first metal-containing layer extends in the second direction.

18. The device according to claim 10, further comprising:
a fourth conductive layer arranged with the second conductive layer in the second direction, and extending in the third direction;
a second semiconductor layer disposed between the fourth conductive layer and the first conductive layer;
a second metal-containing layer disposed between the second semiconductor layer and the first conductive layer;
a second resistance change layer disposed between the second metal-containing layer and the first conductive layer; and
a fifth conductive layer disposed between the third conductive layer and the second semiconductor layer, and extending in a direction crossing the first direction.

19. The device according to claim 18, wherein
the fifth conductive layer extends in the third direction.

20. The device according to claim 18, wherein
the fifth conductive layer extends in the second direction.
